(19) United States
(12) Patent Application Publication
(10) Pub. No.: US 2017/0146187 A1
(43) Pub. Date: May 25, 2017

(54) WALL-HANG APPARATUS OF DISPLAY DEVICE, AND DISPLAY DEVICE

(71) Applicants: LE HOLDINGS (BEIJING) CO., LTD., Beijing (CN); LE SHI ZHI XIN ELECTRONIC TECHNOLOGY (TIAN JIN) LIMITED, Tianjin (CN)

(72) Inventors: Shiming QING, Tianjin (CN); Feng SUN, Tianjin (CN); Cong ZHANG, Tianjin (CN)

(21) Appl. No.: 15/237,847

(22) Filed: Aug. 16, 2016

Related U.S. Application Data
(63) Continuation of application No. PCT/CN2016/081922, filed on May 12, 2016.

(30) Foreign Application Priority Data
Nov. 23, 2015 (CN) 201520943475.4

(51) Int. Cl. F16M 13/02; H05K 7/18; A47B 97/00; F16B 1/00; F16B 47/00

(52) U.S. Cl. CPC F16M 13/02; F16B 1/00; F16B 47/003; A47B 97/00; H05K 7/186; F16B 2001/0035; A47B 2097/005

(57) ABSTRACT

Disclosed are a wall-hang apparatus of a display device, and a display device. The wall-hang apparatus of a display device includes a wall fixture configured to be fixed to a wall, and a display device body fixture configured to be fixed to a display device body, wherein the display device body fixture is hung on the wall fixture, and the display device body fixture is magnetically attracted onto the wall fixture through magnets. With this solution, after the display device is bung on the wall, the display device body and the display device body fixture will not be moved easily relative to the wall fixture due to the attracting magnets to thereby alleviate the risk of falling down from the wall fixture so as to improve the reliability of hanging the display device securely on the wall, and the installation procedure is simple and convenient.

### CROSS-REFERENCE TO RELATED APPLICATIONS

This application is a continuation of International Application No. PCT/CN2016/081922, filed on May 12, 2016, which claims priority to Chinese Patent Application No. 201520943475.4, filed on Nov. 23, 2015, both of which are hereby incorporated by reference in their entireties.

### TECHNICAL FIELD

The present disclosure relates to the field of wall-hang apparatus of a display device and a display device.

### BACKGROUND

A hang bracket of a TV set is a peripheral apparatus of the TV set, which is specifically designed to hang a flat screen TV set, a liquid crystal TV set, etc., on a wall, and widely applied at home, in an office, a meeting room, an exhibition hall, a hotel, an airport, a railway station, a hospital, a bus stop, a shopping mall, and other places.

At present, the TV set is generally Installed on the hang bracket simply by hanging the TV set on the hang bracket, but if the TV set is touched unintentionally by an external force, then the TV set may accidentally fall down from the hang bracket, thus damaging the TV set and even hurting a person.

### SUMMARY

Embodiments of the disclosure provide a wall-hang apparatus of a display device, and a display device so as to improve the reliability of hanging the display device securely on a wall.

Some embodiments of the disclosure provides a wall-hang apparatus of a display device,

the wall-hang apparatus includes a wall fixture configured to be fixed to a wall, and

a display device body fixture configured to be fixed to a display device body, wherein:

the display device, body fixture is hung on the wall fixture, and

the display device body fixture is magnetically attracted onto the wall fixture through magnets.

The wall fixture is arranged horizontally, and

the display device body fixture includes long arms arranged vertically and fixed to the backside of the display device body, and

middle hang pieces fixed to the backsides of the long arms; and

the wall fixture includes a hang plate, and

the middle hang pieces include hang hooks hung on the hang plate,

and the magnets are fixed to the middle hang pieces, and attracted onto the wall fixture.

The backsides of the middle hang pieces have grooves, and

character ‘π’-shaped fixing plates are fixed in the grooves through fasteners, and

both ear tabs of the ‘π’-shaped fixing plates have embedding holes, and

the magnets are embedded in the embedding holes.

Both sides of the middle hang piece have ear tabs, and

the respective ear tabs include embedding holes In which the magnets are embedded.

The magnets are embedded in the embedding holes through strong adhesives or bolts.

The hang plate has hang stop openings, and

the hang hooks are hung in the hang stop openings on the hang plate.

The hang hooks are accommodated on top and bottom sides of the hang plate.

The display device body fixture includes at least two sets of long arms and corresponding middle hang pieces.

Some embodiments of the disclosure provides a display device including a wall-hang apparatus,

the wall-hang apparatus includes a wall fixture configured to be fixed to a wall, and

a display device body fixture configured to be fixed to a display device body, wherein:

the display device body fixture is hung on the wall fixture, and

the display, device body fixture is magnetically attracted onto the wall fixture through magnets.

The wall fixture is arranged horizontally, and

the display device body fixture includes long arms arranged vertically and fixed to the backside of she display device body, and

middle hang pieces fixed to the backsides of the long arms; and

the wall fixture includes a hang plate, and

the middle hang pieces include hang hooks hung on the hang plate,

and the magnets are fixed to the middle hang pieces, and attracted onto the wall fixture.

The backsides of the middle hang pieces have grooves, and

character ‘π’-shaped fixing plates are fixed in the grooves through fasteners, and

both ear tabs of the ‘π’-shaped fixing plates have embedding holes, and

the magnets are embedded in the embedding holes.

Both sides of the middle hang piece have ear tabs, and

the respective ear tabs include embedding holes in which the magnets are embedded,

The magnets are embedded in the embedding holes through strong adhesives or bolts.

The hang plate has hang stop openings, and

the hang hooks are hung in the hang stop openings on the hang plate.

The hang hooks are accommodated on top and bottom sides of the hang plate.

The display device body fixture includes at least two sets of long arms and corresponding middle hang pieces.

The display device includes a flat screen TV set or a flat screen display.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a schematic diagram of a display device assembled with a wall-hang apparatus according to some embodiments of the disclosure;

FIG. 2 is a schematic structural diagram of a wall-hang apparatus according to some embodiments of the disclosure in an explosive view;

FIG. 3 is a schematic structural diagram of a wall-hang apparatus which is assembled according, to some embodiments of the disclosure;

FIG. 4 is a schematic diagram of fixation type of a magnet according to some embodiments of the disclosure;

FIG. 5 is a schematic diagram of a middle hang piece attracted onto a wall fixture according to some embodiments of the disclosure;

FIG. 6 is a schematic diagram of a middle hang piece according to some embodiments of the disclosure.

### REFERENCE NUMERALS

1—Wall fixture

2—Display device body fixture

3—Display device body

4—Magnet

5—Long arm

6—Middle hang piece

11—Hang plate

61—Hang hook

63—character ‘π’-shaped fixing plate

631—Ear tab

632—Embedding hole

111—Hang stop opening

### DETAILED DESCRIPTION

In order to make the objects, technical solutions, and advantages of some embodiments of the disclosure more apparent, the technical solutions according to some embodiments of the disclosure will be described below clearly and fully with reference to the drawings in some embodiments of the disclosure, and apparently some embodiments described below are only a part but not all of some embodiments of the disclosure. Based upon some embodiments here of the disclosure, all the other embodiments which can occur to those skilled in the art without any inventive effort shall tall into the scope of the disclosure.

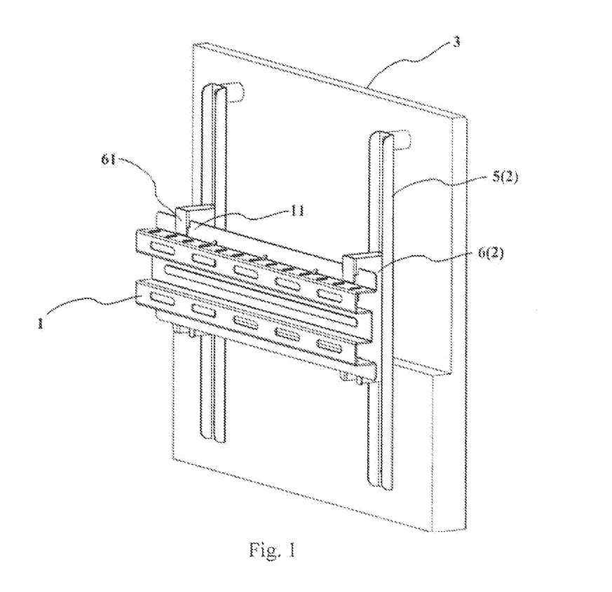

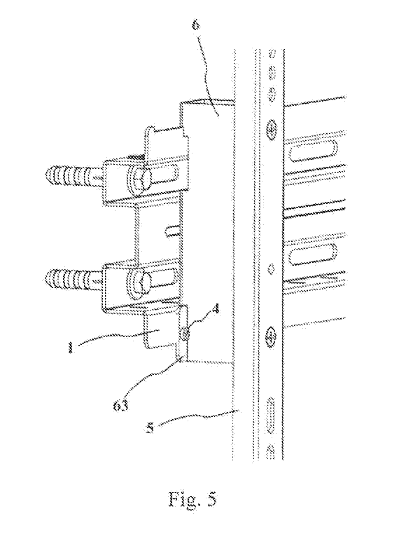

As illustrated in FIG. 1 to FIG. 3 and FIG. 5, a wall-hang apparatus of a display device according to some embodiments of the disclosure includes a wall fixture 1 configured to be fixed to a wall (not illustrated), and a display device body fixture 2 configured to be fixed to a display device body 3, where the display device body fixture 2 is hung on the wall fixture 1, and the display device body fixture 2 is magnetically attracted onto the wall fixture 1 through magnets 4.

In some embodiments, the wall fixture 1 is arranged horizontally, and the display device body fixture 2 includes long arms 5 arranged vertically and fixed to the backside of the display device body 3, and middle hang pieces 6 fixed so the backsides of the long arms 5; and the wall fixture 1 includes a hang plate 11, the middle hang pieces 6 include hang hooks 61 hung on the hang plate 11, and the magnets 4 are fixed to the middle hang pieces 6, and attracted onto the wall fixture 1.

Here a steel plate can be stamped into the wall fixture 1, and the wall fixture 1 can be fixed to the wall through bolts, which can be expansion bolts for further improving load bearing. There are a number of slotted holes opened on the wall fixture so that the requirement for assemble position of the bolts may be lower, and a human operator can select some of the slotted holes flexibly as needed, and fix the wall fixture 1 on the wall through the bolts. The long arms 5 can be fixed to the display device body 3, and also the middle hang pieces 6 can be fixed to the long arms 5, through bolts, where they can be assembled in reality by assembling firstly the long arms 5 with the middle hang pieces 6, and then an assembly including the long arms 5 and the middle hang pieces 6 with the display device body 3; or by assembling firstly the long arms 5 with the display device body 3, and then the middle hang pieces 6 with the long arms 5.

In order to improve a bearing capacity of the wall-hang apparatus to thereby install the display device more firmly, there are at least two sets of long arms 5 and corresponding middle hang pieces 6. Two sets thereof may be sufficient, or three or more sets thereof can be arranged as needed for the specification and the size of the display device.

The magnets 4 can be arranged on the middle hang pieces 6 without limiting any position, form, and number thereof.

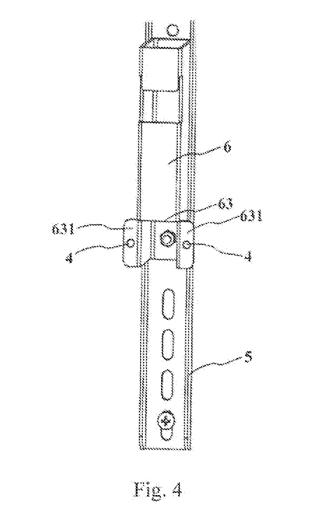

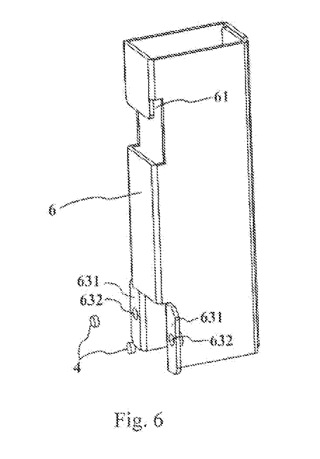

As illustrated in FIG. 4 and FIG. 6, in some embodiments, there are grooves (which are shielded by character ‘π’-shaped fixing plates 63, and thus not illustrated in the figures) on the backsides of the middle hang pieces 6. The character ‘π’-shaped fixing plates 63 includes a main body (not illustrated in the figures) and two ear tabs 631. The shape of the main body matches with the shape and grooves. The character ‘π’-shaped fixing plates 63 are fixed in the grooves through fasteners, there are embedding holes 632 respectively on both ear tabs 631 of the character ‘π’-shaped fixing plates 63, and the magnets 4 are embedded in the embedding holes 632. The magnets 4 can be embedded in the embedding holes 632 through strong adhesives or bolts. Moreover in some embodiments of the disclosure, there are ear tabs on both sides of the middle hang piece, and the respective ear tabs include embedding holes in which the magnets are embedded.

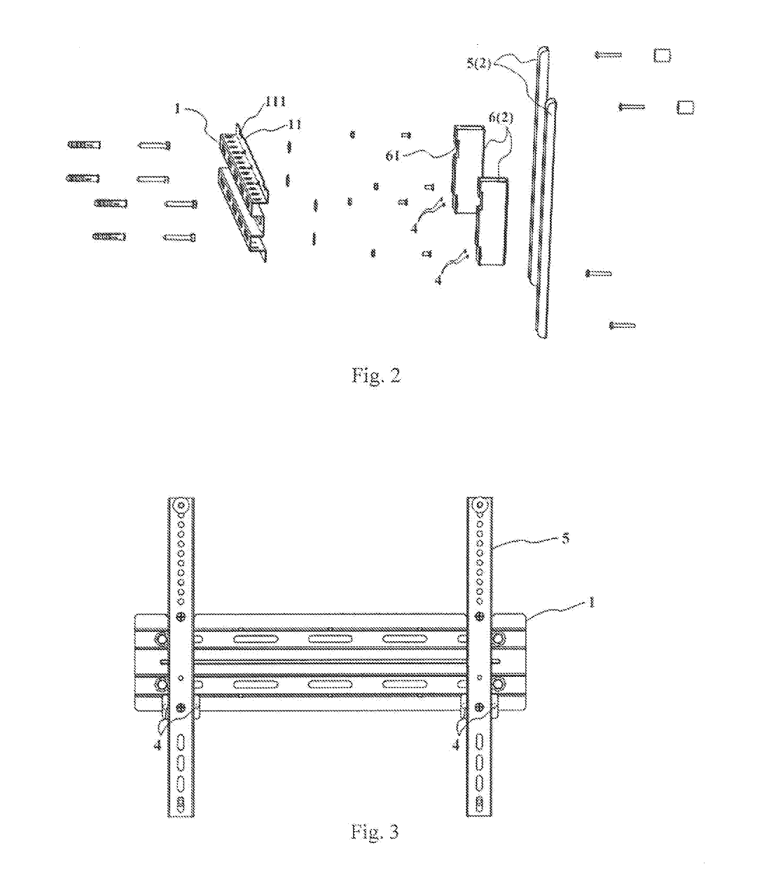

As illustrated in FIG. 1 and FIG. 2, in some embodiments of the disclosure, there are hang stop openings 111 on the hang plate 11, and the hang hooks 61 are hung in the hang stop openings 111 on the hang plate 11; and furthermore the hang hooks 61 are accommodated on top and bottom sides of the hang plate 11. Since the hang stop openings 111 limit the hang hooks 61 in position, the display device body fixture 2 and the display device body 3 will not be moved horizontally relative to the wall fixture 1 to thereby improve the stability of the display device being installed.

With the technical solution according to some embodiments of the disclosure, the display device is hung on the wall in the following operation steps:

The first step is to fix the wall fixture 1 to the wall, and to assemble the long arm 5 with the middle hang piece 6, and then fix an assembly including the long arm 5 and the middle hang piece 6 to the display device body 3; and

The second step is to hang the bang hooks 61 of the middle hang piece 6 in the hang stop hole 111 on the hang plate 11, and to push the display device body 3 toward the wall so that the magnets 4 are attracted onto the wall fixture 1.

With this solution, after the display device is hung on the wall, the display device body 3 and the display device body fixture 2 will not be moved relative to the wall fixture 1 due to the attracting magnets 4 to thereby alleviate the risk of falling down from the wall fixture 1 so as to improve the reliability of hanging the display device securely on the wall, and the installation procedure is simple and convenient.

The display device can be removed by pulling the lower part of the display device body 3 away from the wall so that the magnets 4 are separated from the wall fixture 1, and then lifting up it so that the middle hang piece 6 is disengaged from the wall fixture 1; and disassembling the middle hang piece 6 and the long arm 5 from the display device body 3.

It shall be noted that the display device will not be limited to any type, and the display device can be a flat screen TV set, a flat screen display, etc. A flat screen TV set with a large size can be installed firmly using the wall-hang apparatus very conveniently, and also convenient to be removed.

Some embodiments of the disclosure further provides a display device including the wall-hang apparatus of a display device according to any one of the technical solutions above. The display device can be hung on a wall firmly, and highly securely and reliably. In some embodiments, the display device includes a flat screen TV set or a flat screen display.

Lastly it shall be noted that the respective embodiments above are merely intended to illustrate but not to limit the technical solution of the disclosure; and although the disclosure has been described above in details with reference to some embodiments above, those ordinarily skilled in the art shall appreciate that they can modify the technical solution recited in the respective embodiments above or make equivalent substitutions to a part of the technical features thereof; and these modifications or substitutions to the corresponding technical solution shall also fail into the scope of the disclosure as claimed.

What is claimed is:

1. A wall-hang apparatus of a display device, comprising
a wall fixture configured to be fixed to a wall, and
a display device body fixture configured to be fixed to a display device body, wherein:
the display device body fixture is hung on the wall fixture, and
the display device body fixture is magnetically attracted onto the wall fixture through magnets.

2. The wall-hang apparatus according to claim 1, wherein:
the wall fixture is arranged horizontally, and
the display device body fixture comprises long arms arranged vertically and fixed to a backside of the display device body, and
middle hang pieces fixed to backsides of the long arms; and
the wall fixture comprises a hang plate, and
the middle hang pieces comprise hang hooks hung on the hang plate, and
the magnets are fixed to the middle hang pieces, and attracted onto the wall fixture.

3. The wall-hang apparatus according to claim 2, wherein backsides of the middle hang pieces have grooves and wherein
character ‘π’-shaped fixing plates are fixed in the grooves through fasteners and wherein
both ear tabs of the character ‘π’-shaped fixing plates have embedding holes respectively and wherein
the magnets are embedded in the embedding holes.

4. The wall-hang apparatus according to claim 2, wherein both sides of the middle hang piece have ear tabs, and wherein
the respective ear tabs comprise embedding holes in which the magnets are embedded.

5. The wall-hang apparatus according to claim 3, wherein the magnets are embedded in the embedding holes through adhesives or bolts.

6. The wall-hang apparatus according to claim 4, wherein the magnets are embedded in the embedding holes through adhesives or bolts.

7. The wall-hang apparatus according to claim 2, wherein the hang plate has hang stop openings, and wherein
the hang hooks are hang in the hang stop openings on the hang plate.

8. The wall-hang apparatus according to claim 2, wherein the hang hooks are accommodated on top and bottom sides of the hang plate.

9. The wall-hang apparatus according to claim 2, wherein the display device body fixture comprises at least two sets of long arms and corresponding middle hang pieces.

10. A display device, comprising a wall -hang apparatus,
wherein the wall-hang apparatus comprises a wall fixture configured to be fixed to a wall, and
a display device body fixture configured to be fixed to a display device body, wherein:
the display device body fixture is hung on the wall fixture, and
the display device body fixture is magnetically attracted onto the wall fixture through magnets.

11. The display device according to claim 10, wherein:
the wall fixture is arranged horizontally, and
the display device body fixture comprises long arms arranged vertically and fixed to a backside of the display device body, and
middle hang pieces fixed to backsides of the long arms; and
the wall fixture comprises a hang plate, and
the middle hang pieces comprise hang hooks hung on the hang plate, and
the magnets are fixed to the middle hang pieces, and attracted onto the wall fixture.

12. The display device according to claim 11, wherein backsides of the middle hang pieces have grooves, and wherein
character ‘π’-shaped fixing plates are fixed in the grooves through fasteners, and wherein
both ear tabs of the character ‘π’-shaped fixing plates have embedding holes, and wherein
the magnets are embedded in the embedding holes.

13. The display device according to claim 12, wherein both sides of the middle hang piece have ear tabs, and wherein
the respective ear tabs comprise embedding holes in which the magnets are embedded.

14. The display device according to claim 11, wherein the magnets are embedded in the embedding holes through adhesives or bolts.

15. The display device according to claim 13, wherein the magnets are embedded in the embedding holes through adhesives or bolts.

16. The display device according to claim 11, wherein the hang plate has hang stop openings, and wherein.
the hang hooks are hung in the hang stop openings on the hang plate.

17. The display device according to claim 11, wherein the hang hooks are accommodated on top and bottom sides of the hang plate.

18. The display device according to claim 11, wherein the display device body fixture comprises at least two sets of long arms and corresponding middle hang pieces.

19. The display device according to claim 10, wherein the display device comprises a flat screen TV set or a flat screen display.
